(19) United States
(12) Patent Application Publication
(10) Pub. No.: US 2024/0405083 A1
(43) Pub. Date: Dec. 5, 2024

(54) HIGH MOBILITY TFT DRIVING DEVICE AND MANUFACTURING METHOD THEREOF

(71) Applicant: SEOUL NATIONAL UNIVERSITY R&DB FOUNDATION, Seoul (KR)

(72) Inventors: Soo Yeon LEE, Seoul (KR); Jin Kyu LEE, Seoul (KR)

(73) Assignee: SEOUL NATIONAL UNIVERSITY R&DB FOUNDATION, Seoul (KR)

(21) Appl. No.: 18/696,151

(22) PCT Filed: Jun. 8, 2023
(86) PCT No.: PCT/KR2023/007874

§ 371 Date: Mar. 27, 2024

(30) Foreign Application Priority Data
Jun. 9, 2022 (KR) 10-2022-0070111
May 19, 2023 (KR) 10-2023-0064950

(51) Int. Cl. H01L 29/417; H01L 29/66; H01L 29/786

(52) U.S. Cl. CPC H01L 29/41733; H01L 29/6675; H01L 29/7869; H01L 29/78696

(57) ABSTRACT

The present invention relates to a high-mobility driving element and a method for manufacturing same, the high-mobility driving element comprising: a substrate; an insulating film disposed on the substrate; a channel layer disposed on at least a partial region of the insulating film and including a metal oxide; a source electrode and a drain electrode connected to the channel layer and disposed on the insulating film and either side of the channel layer to face each other; and a protective layer covering all of the channel layer, the source electrode, and the drain electrode, wherein the channel layer comprises a plurality of fluorinated regions in at least a partial region between the source electrode and the drain electrode.

### TECHNICAL FIELD

The present invention relates to a driving device and a manufacturing method thereof, and more specifically, relates to a high mobility thin film transistor (TFT) driving device in which local fluorination treatment is conducted to a channel layer comprising metal oxide and a manufacturing method thereof.

### BACKGROUND ART

A driving device is one kind of semiconductor devices used for converting or amplifying electrical signals, and is used in various fields such as computers, communications, control, medicine, automobiles and home appliances and the like.

Among the semiconductor driving devices, a thin film transistor (TFT) is one of core devices of integrated circuits, and is a device driving a screen using a transistor formed of a thin film. The thin film transistor driving device is known as a technology that has begun to be used mainly in liquid crystal displays, and it is general to configure a liquid crystal panel with a backlight to display colors.

In addition, the thin film transistor driving device is used for OLED and LCD displays used in large/small devices. This device had advantages of low power consumption, providing high resolution and high contrast, and rapid response speed. Moreover, the TFT driving device has an advantage of providing a better viewing angle compared to other types of liquid crystal displays. Element technologies of such a TFT driving device have been continuously developed, and now it is widely used in not only most mobile devices but also high-frequency signal amplifiers, optical communication receivers and the like.

The structure of the thin film transistor is a basic semiconductor material in which the thin film transistor is generally positioned, and consists of a substrate mainly using a silicon wafer, a gate electrode used for controlling currents, a channel providing a path through which currents flow into the area between the gate and substrate, and source and drain electrodes which are electrodes positioned on both sides of the channel and are responsible for inflow and outflow of currents.

Silicon (Si) is most widely used as the semiconductor material of the thin film transistor. Silicon is divided into amorphous silicon and polycrystalline silicon depending on the crystal form, and amorphous silicon has a simple manufacturing process, but has low charge mobility, so has limitations in manufacturing a high-performance thin film transistor, and polycrystalline silicon has high charge mobility, but requires a step of crystallizing silicon, so there is a problem of high manufacturing costs and complicated processes.

In order to complement disadvantages of these amorphous silicon and polycrystalline silicon, a thin film transistor using an oxide semiconductor which has higher electron mobility and a higher on/off ratio than the amorphous silicon, and has a cheaper production cost and higher uniformity than the polycrystalline silicon is attracting attention.

Oxide semiconductors have higher electrical stability and low power consumption than general semiconductor devices, so their utilization is gradually increasing in various fields such as displays, solar cells, sensors and the like. In particular, the utilization is high in the display field, because the performance of displays can be significantly improved due to high electrical stability and low power consumption of oxide semiconductors. In addition, the oxide semiconductors are evaluated as their availability is high in development of devices in the new field such as flexible displays.

### PRIOR ART

### Patent Document

(Patent document 1) Patent Publication No. 10-2014-0087693

### DISCLOSURE

### Technical Problem

An object of the present invention, is to provide a high mobility driving device with innovatively improved mobility of a device, compared to a conventional driving device using an oxide semiconductor and a manufacturing method thereof.

Another object of the present invention is not limited to the object mentioned above, and other objects not mentioned can be clearly understood from the following description by those skilled in the art.

### Technical Solution

In order to solve the afore-mentioned problems, the present invention provides a high mobility driving device, comprising a substrate; an insulating film positioned on the substrate; a channel layer positioned on at least some areas of the insulating film and comprising metal oxide; a source electrode and a drain electrode connected to the channel layer and located on the insulating film to face each other on both sides centered on the channel layer; a protective layer covering all the channel layer, the source electrode and the drain electrode, wherein the channel layer comprises a plurality of local fluorination treatment areas (F treatment areas) in at least some areas between the source electrode and the drain electrode.

According to one example, the area ratio (B) calculated by the following Equation (1) may be within the range of 0.25% to 0.75%.

$$Area ratio ( B ) = \frac{Area of each flourination treatment area \times n}{W \times L} \times 100 \qquad Equation ( 1 )$$

(Wherein L is the interval between the source electrode and drain electrode, and W is the width of the source electrode or drain electrode, and n is the number of fluorination treatment areas.)

According to one example, 2 fluorination treatment areas of the plurality of fluorination treatment areas may be spaced apart from each other as the distance of the width (W) of the source electrode or drain electrode in the width direction, and the plurality of fluorination treatment areas may be arranged in a row at equal intervals from each other in the width direction.

According to one example, the plurality of fluorination treatment areas may be spaced apart from each other at the maximum interval calculated by the following Equation (2), and arranged symmetrically on the basis of the center of the channel layer.

$$Maximum interval = \frac{W}{n - 1} \qquad Equation ( 2 )$$

(Wherein, W is the width of the source electrode or drain electrode, and n is the number of fluorination treatment areas.)

According to one example, the plurality of fluorination treatment areas may be arranged along to the center line (A) extending in the width direction between the source electrode and drain electrode.

According to one example, the plurality of fluorination treatment areas may be formed on the upper surface of the channel layer.

According to one example, the plurality of fluorination treatment areas may be 3 to 9.

According to one example, the metal oxide of the channel layer may comprise indium-gallium-zinc oxide (IGZO).

According to one example, a gate electrode may be further comprised between the substrate and the insulating film.

According to one example, the insulating film comprises silicon oxide.

According to one example, the protective layer comprises silicon oxide.

According to another example of the present invention provides a manufacturing method of a high mobility driving device comprising preparing a substrate; forming a channel layer comprising metal oxide on the substrate; arranging photoresist, in which holes with a certain size are formed on a certain position, on the channel layer; exposing fluorine through the holes; removing the photoresist using a removal solution; forming a source electrode and a drain electrode to face each other on both sides centered on the channel layer; and forming a protective layer to cover all the channel layer, the source electrode and the drain electrode.

According to another example, the metal oxide of the channel layer may comprise indium-gallium-zinc oxide (IGZO).

According to another example, the protective layer may comprise silicon oxide.

According to another example, film forming an insulating film on the substrate may be further comprised before forming the channel layer.

According to another example, forming a gate electrode may be further comprised before film forming the insulating film.

According to another example, the insulating film may comprise silicon oxide.

### Advantageous Effects

According to the configuration of the present invention described above, a high mobility thin film transistor driving device with innovatively improved mobility of a device compared to a conventional driving device using an oxide semiconductor and a manufacturing method thereof can be provided.

### BRIEF DESCRIPTION OF THE DRAWINGS

FIG. 1 is a cross-sectional diagram briefly showing the high mobility driving device according to one example of the present invention cut in the thickness direction.

FIG. 2 is a plan view of the high mobility driving device according to one example of the present invention viewed from above.

FIG. 3 is a schematic diagram of comparative examples and examples of the present invention according to presence or absence of a protective layer configured to cover all the channel layer, source electrode and drain electrode.

FIG. 4 is a graph measuring the transfer curve and mobility (u) of the driving device according to presence or absence of a protective layer configured to cover all the channel layer, source electrode and drain electrode.

FIG. 5 is a graph measuring the transfer curve and mobility (u) of the driving device according to the total area (number of holes) of the fluorination treatment area.

FIG. 6 is a graph measuring the transfer curve and mobility (u) of the driving device according to the interval between the fluorination treatment areas.

FIG. 7 is a perspective view showing the 3D laminated structure of the high mobility driving device according to one example of the present invention.

FIG. 8 is a process schematic diagram illustrating each step of the manufacturing method of the high mobility driving device according to another example of the present invention.

### MODE FOR INVENTION

Examples of the present invention are illustrated for the purpose of describing the technical spirit of the present invention. The scope according to the present invention is not limited to examples or detailed description for these examples presented below.

All technical terms and scientific terms used in the present invention, unless otherwise defined, have meanings commonly understood by those skilled in the art to which the present invention pertains. All terms used in the present invention are selected for the purpose to more clearly describe the present invention, and are not selected to limit the scope according to the present invention.

Expressions such as “comprising”, “with”, “having” and the like used in the present invention, unless otherwise stated in the phrase or sentence comprising the corresponding expression, should be understood as open-ended terms containing possibility to include other examples.

In the present invention, when a part such as a layer, membrane, area, plate and the like is said to be “above” or “on” another part, this not only the case in that it is “directly on” another part, but also the case in that there is another part in between. On the contrary, that it is said to be “above” or “on” the standard part means being positioned above or below of the standard part, and does not necessarily mean being positioned “above” or “on” the direction opposite to gravity.

In the present invention, “plane image” refers to the object of the present invention viewed from above, and “cross-sectional image” means the cross section, in which the object of the present invention is vertically cut, viewed from the side.

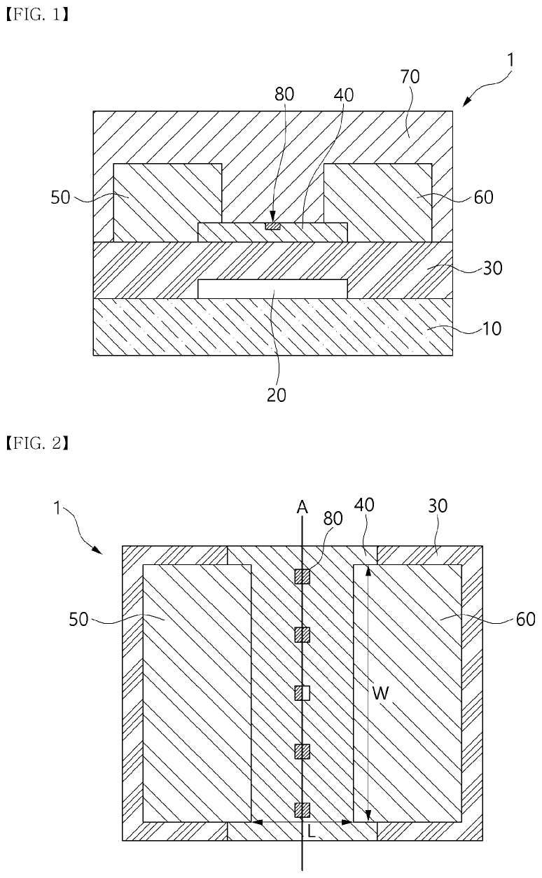

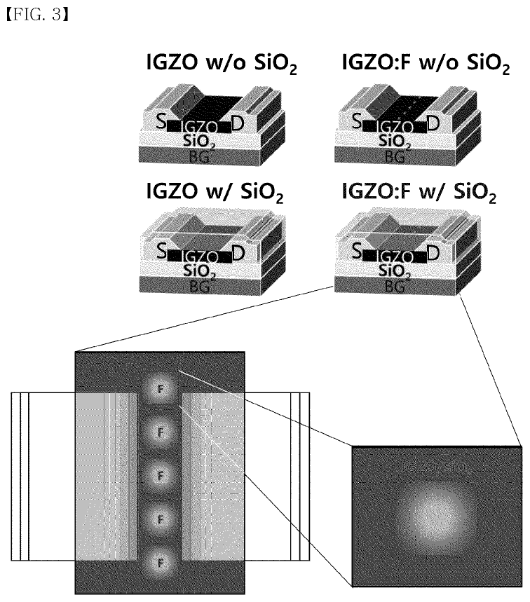

In the present invention, based on the plan view illustrated in FIG. 2, the left and right direction (that is, x direction) is defined as “longitudinal direction”, and the up and down direction (that is, y direction, width direction of the source electrode or drain electrode) is defined as “width direction”, and the direction in which layers are stacked (that is, z direction) is defined as “thickness direction”. In addition, based on the example illustrated in FIG. 2, the left side of the drawing is defined as left and the right side of the drawings is defined as right.

Expressions of the singular form described in the present invention may include a meaning of the plural form unless otherwise mentioned, and this is applied to expressions of the singular form described in the claims in the same manner.

Hereinafter, with reference to the accompanied drawings, the examples of the present invention will be described. In this process, the thickness of the lines or size of the elements or the like illustrated in the drawings may be illustrated exaggeratedly for clarity and convenience of description. In addition, in the description of the following examples, describing the same or corresponding elements repeatedly may be omitted. However, even if the description for the elements is omitted, it is not intended to be that such elements are not included in any example.

In addition, the following examples do not limit the scope of the present invention, but are exemplary points of the elements presented in the claims of the present invention, and examples comprising elements which are included in the technical spirit of the entire description of the present invention and can be substituted with equivalents in the elements of the claims can be included in the scope of the present invention.

At first, with reference to FIG. 1, the high mobility driving device (1) according to one example of the present invention will be described in detail.

FIG. 1 is a cross-sectional diagram briefly showing the high mobility driving device (1) according to one example of the present invention. As shown in FIG. 1, the high mobility driving device (1) according to one example of the present invention, may comprise a substrate (10); an insulating film (30) positioned on the substrate (10); a channel layer (40) positioned on at least some areas of the insulating film (30) and comprising metal oxide; a source electrode (50) and a drain electrode (60) connected to the channel layer (40) and located on the insulating film (30) to face each other on both sides centered on the channel layer (40); a protective layer (70) covering all the channel layer (40), the source electrode (50) and the drain electrode (60), and the channel layer (40) may comprise a plurality of local fluorination treatment areas (F treatment areas) (80) in at least some areas between the source electrode (50) and the drain electrode (60).

With reference to FIG. 1, a gate electrode (20) may be positioned on the substrate (10). However, the gate electrode (20) should not be positioned directly on the substrate (10), and it may be formed at any position as long as the functions of the gate electrode (20) can be exhibited. The gate electrode (20) may be composed of a metal or conductor, and a specific material is not particularly limited, but it is preferable to be formed with at least one metal or alloy selected from the group consisting of aluminum, silver, copper, molybdenum, chrome, tantalum, titanium or alloy thereof.

The insulating film (30) is formed on the substrate (10) and/or the gate electrode (20). The thickness of the insulating film (30) does not specially affect the desired effect of the present invention, so the thickness thereof is not particularly limited, and as non-restrictive one example, it may be formed to 100˜300 nm, which is a thickness commonly used for threshold voltage control. The insulating film (30) comprises an insulating material, and this insulating material may include silicon oxide (SiO₂) or silicon nitride (SiN_{y}). It is preferable that the insulating film (30) is mostly formed through a separate film forming process before forming the channel layer (40).

On at least some areas of the insulating film (30), the channel layer (40) is formed. This channel layer (40) may comprise metal oxide, and preferably, this metal oxide may comprise indium-gallium-zinc oxide (IGZO). The indium-gallium-zinc oxide is a material recently spotlighted as a promising material in the semiconductor industry, and has transparent and flexible characteristics, and in addition, has high electrical conductivity and charge mobility, and therefore, when the channel layer (40) is formed with the indium-gallium-zinc oxide, the responsibility of the device is improved, and thereby, it becomes possible to implement a high-resolution display.

On the insulating film (30), in addition to the channel layer (40), the source electrode (50) and drain electrode (60) are positioned. These source electrode (50) and drain electrode (60) are connected to the channel layer (40) and are positioned to face each other on both sides centered the channel layer (40). In other words, when described with reference to FIG. 1, the source electrode (50) and drain electrode (60) are formed in contact with edges on both sides in the longitudinal direction of the channel layer (40), respectively. As same as the case of the gate electrode (20), the source electrode (50) and drain electrode (60) may be composed of a metal or conductor, and a specific material is not particularly limited, but it is preferable to be formed with at least one metal or alloy selected from the group consisting of aluminum, silver, copper, molybdenum, chrome, tantalum, titanium or alloy thereof.

As non-restrictive one example, one gate electrode (20), one source electrode (50), and one drain electrode (60) can form one thin film transistor (TFT) together with the channel layer (40).

As shown in FIG. 1, the high mobility driving device (1) according to one example of the present invention comprises the protective layer (70) on the channel layer (40), source electrode (50) and drain electrode (60). It is preferable that this protective layer (70) is formed to have a contact surface with all of the channel layer (40), source electrode (50) and drain electrode (60). This protective layer (70) may comprise an inorganic insulating material such as silicon nitrite (SiN_{y}) or silicon oxide (SiO₂), an organic insulating material, and a low dielectric constant insulating material.

As shown in FIG. 2, in the channel layer (4) of the high mobility driving device (1) according to one example of the present invention, a plurality of fluorination treatment areas (80) is formed on at least some areas between the source electrode (50) and drain electrode (60). In addition, the fluorination treatment areas (80) are formed with a significantly very small area compared to the area of the total channel layer (40).

The fluorination treatment areas (80) may be formed on the channel layer (40) by exposing and diffusing fluorine gas only in some areas using photoresist and the like. In the present invention, a part of some areas exposed and diffused to the fluorine gas is defined as ‘local fluorination treatment area’. In this case, the plurality of fluorination treatment areas (80) is formed by diffusing fluorine in the thickness direction from the upper surface of the channel layer (40), and the plurality of fluorination treatment areas (80) is formed on the upper surface of the channel layer (40). Then, the plurality of fluorination treatment areas is formed to have an intended interval as a point collocation method by confirming that a different effect is implemented from treating the total areas on the channel layer with fluorine and treating fluorine only to the local areas.

In the high mobility driving device (1) according to one example of the present invention, it is important that a combination area is formed between the fluorination treatment areas (80) and protective layer (70). In other words, in the present invention, the protective layer (70) is formed to directly face on the channel layer (40), and then, the fluorination treatment areas (80) are formed on the upper surface of the channel layer (40), and thus the combination area can be naturally formed between the fluorination treatment areas (80) and protective layer (70).

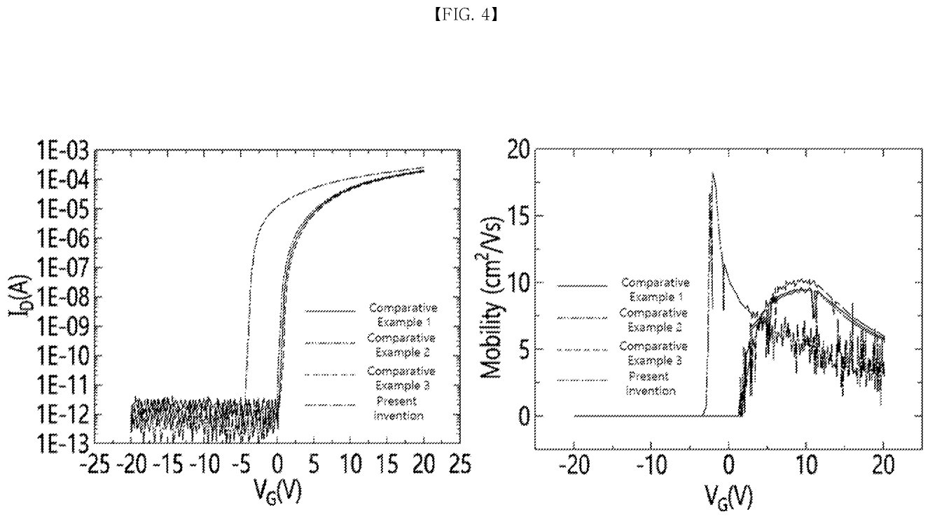

FIG. 3 is a schematic diagram of comparative examples (Comparative example 1 to Comparative example 3 of FIG. 4) and examples of the present invention according to presence or absence of a protective layer configured to cover all the channel layer, source electrode and drain electrode.

FIG. 4 shows experimental data verifying the mobility increasing effect of the driving device (1) by the combination area between the fluorination treatment areas (80) and protective layer (70) for each Comparative example and Example shown in FIG. 3. As could be confirmed in FIG. 4, it could be confirmed that when the combination area is formed between the fluorination treatment areas (80) and protective layer (70) (Inventive example 1), compared to the case in that any one of the fluorination treatment areas (80) and protective layer (70) is lacking, the threshold voltage (Vₜₕ) is reduced and the mobility is significantly improved.

Returning to FIG. 2, it is preferable that the plurality of fluorination treatment areas (80) is arranged along the center line (A) extending in the width direction between the source electrode (50) and drain electrode (60) shown in FIG. 2. In addition, it is preferable that the plurality of fluorination treatment areas (80) is arranged in a row at equal intervals, while being arranged along the center line (A) extending in the width direction between the source electrode (50) and drain electrode (60). In other one example, the plurality of fluorination treatment areas may be formed to be arranged not simply in one row, but in two rows or three rows.

In the present invention, the shape of the fluorination treatment areas (80) is not particularly limited, and even if it is formed in any shape, such as square, rectangle, circle, oval, or the like, when it is formed as a local area, the effect intended by the present inventor can be obtained. In addition, the number of the fluorination treatment areas (80) is not particularly limited, but in consideration of the size of a common device and the area ratio (B) described below, the number of the fluorination treatment areas (8) is preferably 3 to 9, and it is more preferably 3 to 5.

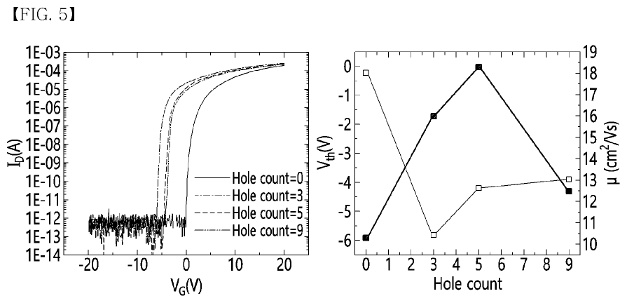

FIG. 5 is a graph measuring the transfer curve and mobility (u) of the driving device according to the total area (number of holes) of the fluorination treatment area.

The inventors of the present invention have studied in depth on how changes in the total area of the fluorination treatment areas (80) affect the mobility of the driving device (1). As a result, it was confirmed that as the number of the fluorination treatment areas (80) increased (that is, as the total area increases), the mobility of the device increased to a certain range, but when fluorination treatment was excessive (that is, when the number of the fluorination treatment areas (80) was excessively large), the mobility of the driving device (1) was rather reduced again. According to these experimental results, the inventors of the present invention recognized that the total area of the fluorination treatment areas (80) should be controlled within a certain range, and the area of the fluorination treatment areas (80) was limited using the ratio of the total area of the fluorination treatment areas (80) to the area of the channel layer (40) between the source electrode (50) and drain electrode (60).

Specifically, the total area of the fluorination treatment areas (80) (that is, area combining all areas of each of local fluorination treatment areas (80)) may be limited to the area ratio (B) to the area (WXL) of the channel layer (40) between the source electrode (50) and drain electrode (60). In other words, the area ratio (B) may be calculated by the following Equation (1), and the value is preferably within the range of 0.25% to 0.75%, and it is more preferably within the range of 0.25% to 0.42%.

$$Area ratio ( B ) = \frac{Area of each flourination treatment area \times n}{W \times L} \times 100 \qquad Equation ( 1 )$$

Herein, L is the interval between the source electrode (50) and drain electrode (60), and W is the width of the source electrode (50) or drain electrode (60), and n is the number of fluorination treatment areas (80).

FIG. 6 is a graph measuring the transfer curve and mobility (μ) of the driving device according to the interval between the fluorination treatment areas.

On the other hand, the inventors of the present invention studied the effect of the interval the fluorination treatment areas (80) on the mobility of the driving device (1). As a result, the inventors of the present invention confirmed that the mobility increased significantly when the interval of the plurality of fluorination treatment areas (80) was a maximum interval under the same conditions.

Reflecting these experimental results, 2 fluorination treatment areas (80) of the plurality of fluorination treatment areas (80) are preferably spaced apart from each other as much as the distance of the width (W) of the source electrode (50) or drain electrode (60) in the width direction. In other words, as shown in FIG. 2, any one fluorination treatment areas (80) of the plurality of fluorination treatment areas (80) is located on an extension of the upper edge of the source electrode (50) or drain electrode (60) based on FIG. 2, and the other fluorination treatment area (80) of the plurality of fluorination treatment areas (80) is located on an extension of the lower edge of the source electrode (50) or drain electrode (60) based on FIG. 2, and thus, as a result, these two fluorination treatment areas (80) are spaced apart as much as the distance of the width (W) of the source electrode (50) or drain electrode (60). If such conditions are satisfied, the two fluorination treatment areas (80) adjacent to each other may be arranged along the center line (A) extending in the width direction between the source electrode (50) and drain electrode (60) at a maximum interval.

As non-restrictive one example, the plurality of fluorination treatment areas (80) may be symmetrically arranged on the basis of the center of the channel layer (40) while being spaced apart from each other at a maximum interval calculated by the following Equation (2). Herein, the center of the channel layer (40) can be defined as a center right in the middle of the channel layer (40) area between the source electrode (50) or drain electrode (60) determined by the width (W) of the source electrode (50) or drain electrode (60) and an interval (L) between the source electrode (50) or drain electrode (60).

$$Maximum interval = \frac{W}{n - 1} \qquad Equation ( 2 )$$

Herein, W is the width of the source electrode (50) or drain electrode (60), and n is the number of the fluorination treatment areas (80).

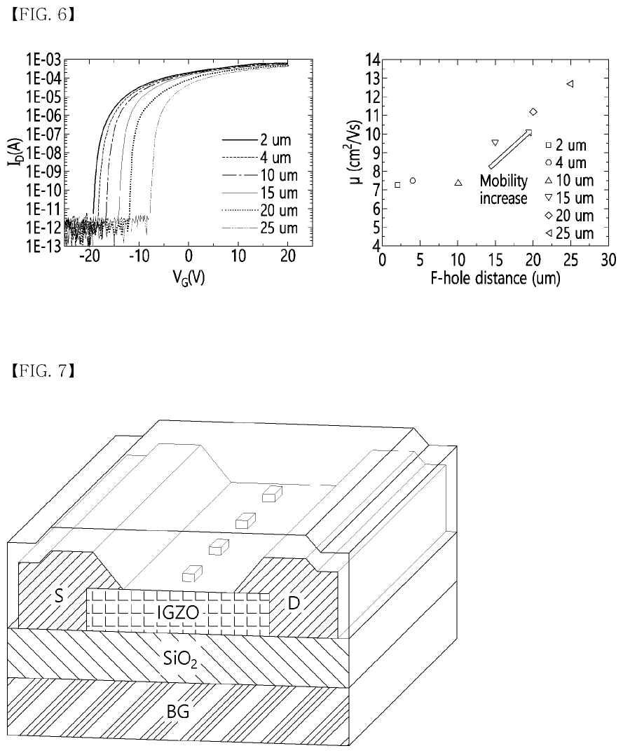

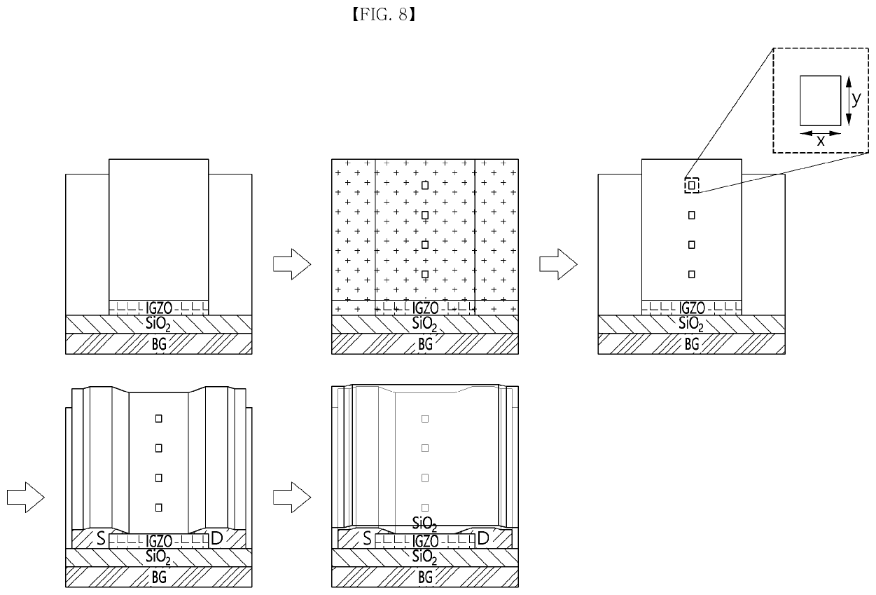

FIG. 7 is a perspective view showing the 3D laminated structure of the high mobility driving device according to one example of the present invention. When the laminated structure of the high mobility driving device according to the example of the present invention described above is easily expressed, it is as FIG. 7.

Next, the manufacturing method of the high mobility driving device (1) according to one example of the present invention will be described. However, the manufacturing method described in the following is just any one example of various methods of manufacturing the high mobility driving device (1) according to one example of the present invention.

FIG. 8 is a process schematic diagram illustrating each step of the manufacturing method of the high mobility driving device according to another example of the present invention.

At first, the substrate (10) is prepared, and the gate electrode (20) and the insulating layer are formed on it. If the gate electrode (20) is formed on another position or the insulating layer is already formed, this step may be omitted.

Then, the channel layer (40) comprising metal oxide, preferably, indium-gallium-zinc oxide (IGZO) is formed on the insulating layer. The method for forming the channel layer (40) is not particularly limited, and a known technology such as solution processing, atomic layer deposition (ALD), sputter deposition (DC or RF), and the like may be used.

After arranging photoresist in which holes with a certain size at a certain position on the channel layer (40), fluoride is supplied and exposed so that fluoride is diffused to the channel layer (40) through the holes. After that, the photoresist is removed using removal solution such as acetone and the like.

Then, when the source electrode (50) and drain electrode (60) are formed to face each other on both sides centered on the channel layer (40), and the protective layer (70) is formed to cover all the channel layer (40), the source electrode (50) and the drain electrode (60), the high mobility driving device (1) according to one example of the present invention can be manufactured.

### Examples

Hereinafter, the effects of the high mobility driving device (1) according to one example of the present invention will be described through experimental results.

### (Method for Measuring Threshold Voltage (Vₜₕ))

In the experiment of the present invention, the device was measured through a probe station and a semiconductor analyzer (Keithley 4200-SCS), and as the device measurement condition, it was progressed at V_{DS}=10.1 V, which is the saturation section. The threshold voltage was extracted through constant current method, and this method extracts the threshold voltage at a designated current value. The designated current value used in the present experiment is I_{DS}=10 pA.

### (Method for Measuring Mobility (μ))

In the experiment of the present invention, the device was measured through a probe station and a semiconductor analyzer (Keithley 4200-SCS), and as the device measurement condition, it was progressed at V_{DS}=10.1 V, which is the saturation section. For the mobility, extraction was progressed in the saturation region rather than linear region, and the mobility can be derived by substituting the current in the saturation region into Equation (3).

$${μ}_{sat} = ( \frac{2 L}{W} ) ( \frac{1}{{C}_{ox}} ) {( \frac{d \sqrt{{I}_{D}}}{{dV}_{GS}} )}^{2} \qquad Equation ( 3 )$$

### (Experiment 1)

At first, as an invention example, the high mobility driving device (1) having the same structure as FIG. 1 was manufactured according to the manufacturing method described above (Invention example 1). Herein, as the insulating film (30), silicon oxide (SiO₂) was used, and it was manufactured as the width (W) of the source electrode (50) and drain electrode (60) was 50 μm and the interval (L) between the source electrode (50) and drain electrode (60) was 6 μm. In addition, a total of 5 fluorination treatment areas (80) were formed in a square shape of 0.5 μm in width and 0.5 μm in length, respectively, and the protective layer (70) composed of silicon oxide (SiO₂) was formed to cover all the channel layer (40), source electrode (50) and drain electrode (60).

On the other hand, Comparative example 1 is the case in that all the fluorination treatment areas (80) and protective layer (70) are not formed in Invention example 1 above, and Comparative example 2 is the case in that only the fluorination treatment areas (80) are not formed, and Comparative example 3 is the case in that only the protective layer (70) is not formed. For each of Invention example 1, and Comparative examples 1 to 3, under the same conditions, the threshold voltage (Vₜₕ) and mobility (μ) of the driving device (1) were measured, and the results were shown in Table 1 and FIG. 3.

TABLE 1

| | Whether to | Whether to | Threshold | |
|---|---|---|---|---|
| | form a | form a | voltage | Mobility |
| | fluorination | protective | (Vₜₕ) | (μ) |
| Classification | treatment area | layer | (V) | (cm²/Vs) |
| Invention | ◯ | ◯ | −4.09 | 18.31 |
| example 1 | | | | |
| Comparative | X | X | 0.6 | 9.59 |
| example 1 | | | | |
| Comparative | ◯ | X | 0.3 | 9.58 |
| example 2 | | | | |
| Comparative | X | ◯ | 0.4 | 10.29 |
| example 3 | | | | |

From the experimental results, Invention example 1 which had the channel layer (40) in which fluorination treatment was locally performed, and this channel layer (40) formed the protective layer (70) and the combination area, showed the results that the threshold voltage (Vₜₕ) of the gate voltage (V_{G}) became lower, and the mobility of the device increased, compared to Comparative examples 1 to 3 in which at least one of the fluorination treatment areas (80) and protective layer (70) was lacked.

Through these results of Experiment 1, it could be confirmed that an effect of increasing the mobility of the device was shown, when the combination area of fluoride (F) and silicon oxide (SiO₂) was locally generated.

### (Experiment 2)

According to the manufacturing method described above, 4 high mobility driving device (1) having the structure as FIG. 1 were manufactured. Herein, as the insulating film (30), silicon oxide (SiO₂) was used, and it was manufactured as the width (W) of the source electrode and drain electrode was 50 μm and the interval (L) between the source electrode and drain electrode was 6 μm. In addition, the fluorination treatment areas (80) were formed in a square shape of 0.5 μm in width and 0.5 μm in length, respectively, and for each example, the number of the fluorination treatment areas (80) was formed each differently to 0, 3, 5 and 9. After that, the protective layer (70) composed of silicon oxide (SiO₂) was formed to cover all the channel layer (40), source electrode (50) and drain electrode (60).

For Invention examples 2 and 3, Comparative examples 4 and 5, under the same conditions, the threshold voltage (Vₜₕ) and mobility (μ) of the driving device (1) were measured, and the results were shown in Table 2 and FIG. 4.

TABLE 2

| | Number of | Area | Threshold | |
|---|---|---|---|---|
| | fluorination | ratio (B) | voltage (Vₜₕ) | Mobility (μ) |
| Classification | treatment areas | (%) | (V) | (cm²/Vs) |
| Comparative | 0 | 0 | −0.2 | 10.28 |
| example 4 | | | | |
| Invention | 3 | 0.25 | −5.8 | 16 |
| example 2 | | | | |
| Invention | 5 | 0.42 | −4.2 | 18.3 |
| example 3 | | | | |
| Invention | 9 | 0.75 | −3.9 | 12.5 |
| example 4 | | | | |

As a result of the experiment, as the number of the fluorination treatment areas increased, the threshold voltage was lowered and the mobility was improved. In the section in which the area ratio (B) was around 0.4%, the mobility showed a peak, and when the fluorination treatment was excessive, the results that the threshold voltage increased slightly and the mobility was gradually reduced were shown.

### (Experiment 3)

The present inventors conducted an additional experiment to investigate the changes in the threshold voltage (Vₜₕ) and mobility (μ) of the driving device depending on the width direction interval of the fluorination treatment areas for the high mobility driving device according to one example of the present invention.

As same as Experiment 1 or Experiment 2, 6 high mobility driving devices having the structure as FIG. 1 were manufactured according to the manufacturing method described above. Herein, as the insulating film, silicon oxide (SiO₂) was used, and it was manufactured as the width (W) of the source electrode and drain electrode was 50 μm and the interval (L) between the source electrode and drain electrode was 6 mm.

Three fluorination treatment areas were formed in a square shape of 0.5 μm in width and 0.5 μm in length, respectively, and then, the protective layer composed of silicon oxide (SiO₂) was formed to cover all the channel layer, source electrode and drain electrode.

For each example, one fluorination treatment area was formed right in the middle, and the remaining 2 positions were changed to change the interval between the fluorination treatment areas differently, and the threshold voltage (Vₜₕ) and mobility (μ) of the driving device were measured, and the results were shown in Table 3 and FIG. 5.

TABLE 3

| | Width direction | | |
|---|---|---|---|
| | interval between | Threshold voltage | |
| | fluorination | (Vₜₕ) | Mobility (μ) |
| Classification | treatment areas (μm) | (V) | (cm²/Vs) |
| Invention | 2 | −18.7 | 7.27 |
| example 5 | | | |
| Invention | 4 | −17.7 | 7.49 |
| example 6 | | | |
| Invention | 10 | −16.2 | 7.34 |
| example 7 | | | |
| Invention | 15 | −13.7 | 9.59 |
| example 8 | | | |
| Invention | 20 | −11.7 | 11.2 |
| example 9 | | | |
| Invention | 25 | −7.4 | 12.9 |
| example 10 | | | |

As a result of the experiment, for the interval between the fluorination treatment areas (80), it was shown that the movement characteristics of the device were best when the interval was maximum on the basis of the center and was spread evenly as Invention example 10. In other words, it can be interpreted as having the best movement characteristics when the fluorination treatment areas (80) are spaced apart as much as the maximum interval (For example, as the experiment, when the width (W) is 50 μm, and the number of the fluorination treatment areas (80) is 3, the maximum interval is 25 μm) calculated by the afore-mentioned Equation (2).

The above description is illustratively describing the technical spirit of the present invention only, and those skilled in the art to which the present invention belongs can make various modification and variation in a range without departing from essential characteristics of the present invention. Therefore, the examples disclosed in the present invention are not intended to limit the technical spirit of the present invention, but are intended to describe it, and the scope of the technical spirit of the present invention is not limited. The scope of the present invention should be construed according to the claims below, and all the technical spirits within the equivalent range thereto should be construed as being included in the scope of the present invention.

### DESCRIPTION OF THE SYMBOLS

1: Driving device
10: Substrate
20: Gate electrode
30: Insulating film
40: Channel layer
50: Source electrode
60: Drain electrode
70: Protective layer
80: Fluorination treatment area
W: Width of source electrode or drain electrode
L: Interval between source electrode and drain electrode
A: Center line extending in the width direction between source electrode and drain electrode

1. A high mobility driving device,
comprising
a substrate;
an insulating film positioned on the substrate;
a channel layer positioned on at least some areas of the insulating film and comprising m etal oxide;
a source electrode and a drain electrode connected to the channel layer and located on th e insulating film to face each other on both sides centered on the channel layer;
a protective layer covering all the channel layer, the source electrode and the drain electr ode,
wherein the channel layer comprises a plurality of local fluorination treatment areas (F tr eatment areas) in at least some areas between the source electrode and the drain electrode.

2. The high mobility driving device according to claim 1,
wherein the area ratio (B) calculated by the following formula (1) is within the range of 0.25% to 0.75%.
$$Area ratio ( B ) = \frac{Area of each flourination treatment area \times n}{W \times L} \times 100 \qquad Equation ( 1 )$$
(Wherein L is the interval between the source electrode and drain electrode, and W is the width of the source electrode or drain electrode, and n is the number of fluorination treatment are as.)

3. The high mobility driving device according to claim 1,
wherein 2 fluorination treatment areas of the plurality of fluorination treatment areas are s paced apart from each other as the distance of the width (W) of the source electrode or drain elec trode in the width direction, and
the plurality of fluorination treatment areas is arranged in a row at equal intervals from ea ch other in the width direction.

4. The high mobility driving device according to claim 1,
wherein the plurality of fluorination treatment areas is spaced apart from each other at the maximum interval calculated by the following Equation (2), and arranged symmetrically on the basis of the center of the channel layer.
$$Maximum interval = \frac{W}{n - 1} \qquad Equation ( 2 )$$
(Wherein, W is the width of the source electrode or drain electrode, and n is the number o f fluorination treatment areas.)

5. The high mobility driving device according to claim 1,
wherein the plurality of fluorination treatment areas is arranged along to the center line (A) extending in the width direction between the source electrode and drain electrode.

6. The high mobility driving device according to claim 1,
wherein the plurality of fluorination treatment areas is formed on the upper surface of the channel layer.

7. The high mobility driving device according to claim 1,
wherein the plurality of fluorination treatment areas is 3 to 9.

8. The high mobility driving device according to claim 1,
wherein the metal oxide of the channel layer comprises indium-gallium-zinc oxide (IGZ O).

9. The high mobility driving device according to claim 1,
further comprising a gate electrode between the substrate and the insulating film.

10. The high mobility driving device according to claim 1,
wherein the insulating film comprises silicon oxide.

11. The high mobility driving device according to claim 1,
wherein the protective layer comprises silicon oxide.

12. A manufacturing method of the high mobility driving device according to cl aim 1, comprising
preparing a substrate;
forming a channel layer comprising metal oxide on the substrate;
arranging photoresist, in which holes with a certain size are formed on a certain position, on the channel layer;
exposing fluorine through the holes;
removing the photoresist using a removal solution;
forming a source electrode and a drain electrode to face each other on both sides centered on the channel layer; and
forming a protective layer to cover all the channel layer, the source electrode and the drai n electrode.

13. The manufacturing method of the high mobility driving device according to claim 12,
wherein the metal oxide of the channel layer comprises indium-gallium-zinc oxide (IGZ O).

14. The manufacturing method of the high mobility driving device according to claim 12,
wherein the protective layer comprises silicon oxide.

15. The manufacturing method of the high mobility driving device according to claim 12,
further comprising film forming an insulating film on the substrate, before forming the ch annel layer.

16. The manufacturing method of the high mobility driving device according to claim 15,
further comprising forming a gate electrode before film forming the insulating film.

17. The manufacturing method of the high mobility driving device according to claim 15,
wherein the insulating film comprises silicon oxide.
